(19) United States
(12) Patent Application Publication
(10) Pub. No.: US 2024/0266413 A1
(43) Pub. Date: Aug. 8, 2024

(54) SEMICONDUCTOR POWER TRANSISTOR DESIGN WITH INTEGRATED AUXILIARY GATE CONDUCTOR FOR ON-CHIP COOLING AND HEAT EXTRACTION

(71) Applicant: Integra Technologies, Inc., El Segundo, CA (US)

(72) Inventor: Gabriele Formicone, Chandler, AZ (US)

(21) Appl. No.: 18/415,013

(22) Filed: Jan. 17, 2024

Related U.S. Application Data
(60) Provisional application No. 63/442,946, filed on Feb. 2, 2023.

(51) Int. Cl. H01L 29/423; H01L 23/00; H01L 23/495; H01L 29/78

(52) U.S. Cl. CPC H01L 29/42376; H01L 23/49562; H01L 29/7816; H01L 24/48; H01L 24/49; H01L 2224/48245; H01L 2224/49052

(57) ABSTRACT

A semiconductor power transistor is described with on-chip heat extraction. A semiconductor die a substrate, a plurality of source electrodes formed as fingers of source metallization layers over the substrate, a plurality of drain electrodes formed as fingers of drain metallization layers over the substrate, a plurality of main gate electrodes, each being between a source electrode and a drain electrode, a dielectric layer over the plurality of source electrodes, the plurality of drain electrodes, and the plurality of main gate electrodes, and a plurality of auxiliary gate electrodes, each being between a source electrode and a drain electrode, and above a respective main gate electrode with a dielectric layer between the main gate electrode and the respective auxiliary gate electrode, the auxiliary gate electrodes being thermally coupled to the respective main gate electrode and configured to draw heat from the main gate electrode away from the substrate.

### CROSS-REFERENCE TO RELATED APPLICATIONS

The present application claims the priority of prior provisional patent application Ser. No. 63/442,946, filed Feb. 2, 2023, entitled “Semiconductor Radio Frequency Power Transistor Design with Integrated Auxiliary Gate Conductor for On-Chip Cooling and Heat Extraction” by Gabriele Formicone, the contents of which are incorporated by reference herein.

### TECHNICAL FIELD

The present invention relates to the field of semiconductor power transistors and, in particular, to such a transistor with an integrated auxiliary gate conductor for on-chip heat extraction.

### BACKGROUND

A semiconductor power device, e.g., a transistor, usually generates a substantial amount of heat at and near its active region. Usually, a maximum temperature, often referred to as the maximum junction temperature, is specified which the temperature of the active region should not exceed so that the semiconductor power device may be operated safely and reliably. Such heat limitations apply to many types of transistors in different applications, e.g., Silicon LDMOS (laterally-diffused metal oxide semiconductor), VDMOS (voltage-diffused metal oxide semiconductor), IGBT (Insulated Gate Bipolar Transistors), BJT (Bipolar Junction Transistor), and emerging SiC (Silicon Carbide) FETs (Field Effect Transistors).

The junction temperature may be determined by the dissipated power (measured in watts) times the thermal impedance (measured in degrees per watt). In typical applications, the thermal impedance is determined by the heat flow from the device junction or active region at the top surface and inner region of the semiconductor die, down through the die substrate material.

High-power RF (Radio Frequency) transistors switch very quickly to meet the intended frequencies. The higher speed benefits from a smaller main gate electrode to reduce electrical charge transit time. However, with high power, e.g., high voltage and high current, a large amount of dissipated heat is generated at the drain-side edge of the main gate electrode. Generally, the semiconductor materials of a transistor that allow for processing signals at high frequencies, such as radio frequency (RF), microwave, and millimeter wave, have a high thermal impedance. This causes the heat generated by the high speed switching to accumulate in the active region of the transistor. The high effective junction or active channel temperatures impede the reliability and efficiency of the transistor.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

In an example, a semiconductor power die includes a substrate, a plurality of source electrodes formed as fingers of source metallization layers over the substrate, a plurality of drain electrodes formed as fingers of drain metallization layers over the substrate, a plurality of main gate electrodes, each being between a source electrode and a drain electrode, a dielectric layer over the plurality of source electrodes, the plurality of drain electrodes, and the plurality of main gate electrodes, and a plurality of auxiliary gate electrodes, each being between a source electrode and a drain electrode, and above a respective main gate electrode with a dielectric layer between the main gate electrode and the respective auxiliary gate electrode, the auxiliary gate electrodes being thermally coupled to the respective main gate electrode and configured to draw heat from the main gate electrode away from the substrate.

Further examples include a top surface opposite the substrate, wherein the auxiliary gate electrodes are configured to draw heat in a direction from an active area of the semiconductor power die.

In further examples the auxiliary gate electrodes are formed of auxiliary metallization layers over the substrate, the auxiliary metallization layers being formed of the same material as the source metallization layers.

In further examples the auxiliary gate electrodes have a greater cross-sectional area than the main gate electrodes.

In further examples the auxiliary gate electrodes have a greater volume than the main gate electrodes.

In further examples a main gate electrode has a cross-sectional area no greater than 1 square micrometer and the auxiliary gate electrode has a cross-sectional area of at least 15 square micrometers.

In further examples the auxiliary gate electrodes are over a respective main gate electrode and over a respective source gate electrode.

Further examples include a plurality of gate extensions each connected to an auxiliary gate electrode and to a respective main gate electrode, wherein the auxiliary gate electrodes are thermally coupled to the respective main gate electrodes through the respective gate extensions.

In further examples the gate extensions are formed as VIAs (Vertical Integrated Accesses).

In further examples the main gate electrodes are elongated along the source electrodes and the drain electrodes and wherein each auxiliary gate electrode has a plurality of gate extensions spaced along the direction of elongation of the source electrodes.

In further examples the auxiliary gate electrodes are elongated along respective fingers of the source electrodes, the semiconductor power die further comprising a second auxiliary gate electrode elongated in the direction of the fingers of the source electrode, alongside at least a portion of the plurality of auxiliary gate electrodes.

In further examples the second auxiliary gate electrodes are thermally coupled to a respective main gate electrode.

In further examples the second auxiliary gate electrodes are thermally coupled to a respective main gate electrode through a respective first auxiliary gate electrode.

In further examples the second auxiliary gate electrodes are thermally coupled to a respective main gate electrode through a plurality of VIAs.

In further examples the second auxiliary gate electrodes are thermally coupled to a respective main gate electrode through a lateral bridge.

In further examples the substrate is attached to a package flange, the semiconductor power die further comprising a gate pad electrically coupled to the plurality of main and auxiliary gate electrodes and thermal conductors coupled to the gate pad to the package flange.

In an example a semiconductor power device includes a base plate, an input lead, an output lead, a field effect transistor (FET) power die disposed over the base plate, wherein the FET power die includes a set of source electrodes, a set of drain electrodes, and a set of gate electrodes disposed directly over an active region, wherein the set of gate fingers is configured to receive an input signal from the input lead, and wherein the FET power die is configured to process the input signal to generate an output signal at the set of drain fingers for routing to the output lead. The FET power die includes a substrate attached to the base plate, a dielectric layer over the plurality of source electrodes, the plurality of drain electrodes, and the plurality of main gate electrodes, and a plurality of auxiliary gate electrodes, each being between a source electrode and a drain electrode, and above a respective main gate electrode with a dielectric layer between the main gate electrode and the respective auxiliary gate electrode, the auxiliary gate electrodes being thermally coupled to the respective main gate electrode and configured to draw heat from the main gate electrode away from the substrate.

In further examples auxiliary gate electrodes are over a respective main gate electrode and over a respective source gate electrode.

Further examples include a plurality of gate extensions each connected to an auxiliary gate electrode and to a respective main gate electrode, wherein the auxiliary gate electrodes are thermally coupled to the respective main gate electrodes through the respective gate extensions.

In further examples the main gate electrodes are elongated along the source electrodes and the drain electrodes and wherein each auxiliary gate electrode has a plurality of gate extensions spaced along the direction of elongation of the source electrodes.

### BRIEF DESCRIPTION OF THE DRAWINGS

FIG. 1A is a top view diagram of an exemplary semiconductor power device in accordance with an aspect of the disclosure.

FIG. 1B is a cross-sectional side view diagram of the semiconductor power device along line 1B-1B of FIG. 1A in accordance with an aspect of the disclosure.

FIG. 2 is a top view diagram of a portion of the semiconductor power die of FIG. 1A showing main and auxiliary gate electrodes in accordance with an aspect of the disclosure.

FIG. 3 is a top view diagram further enlarged of a portion of the semiconductor power die of FIG. 2 in accordance with an aspect of the disclosure.

FIG. 4 is a two-dimensional side view cross-sectional diagram of a FET die structure through an area of the main gate electrode in between two gate extension points in accordance with an aspect of the disclosure.

FIG. 5 is a two-dimensional side view cross-sectional diagram of the FET die structure of FIG. 4 through an area of the main gate electrode at the gate extension zone in accordance with an aspect of the disclosure.

FIG. 6 is a top view enlarged diagram of an alternative power FET in accordance with an aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A semiconductor transistor design and operation are described herein for multiple high temperature purposes including a radio frequency high power transistor. The transistor includes on-chip cooling through auxiliary gate electrodes. The auxiliary gate electrodes provide increased dissipated heat outflow and reduced thermal impedance. Second and higher order harmonic terminations allow higher efficiency at the input through increased input capacitance and reduced input resistance for a more uniform signal propagation and reduced input impedance.

Heat extraction from the top surface of the die is increased using an auxiliary thick metal connector, made with e.g., electroplated gold or copper, to synthesize an auxiliary gate electrode. The connector is connected in parallel to the main gate electrode which is much smaller to facilitate fast switching. The auxiliary gate electrodes may be formed over the active regions of the semiconductor power die. In the case of a semiconductor power die configured as a field effect transistor (FET) type device, the active region is referred to as the channel. Thus, as exemplified herein, the electrical conductors may be formed between the source fingers and the drain fingers of the FET type device. In the case of a bipolar junction type device, the active region is referred to as the p-n and n-p junctions. As an example, the electrical conductors may be formed as metallization over the p-n or n-p junction of the bipolar junction type device.

While the present disclosure is provided in the context of a high-power (RF) Gallium-Nitride (GaN) on Silicon-Carbide (SiC) die, the structures and techniques herein may be applied to any high-power semiconductor technology being used at any frequency from direct current (DC) to millimeter wave, e.g., any digital, analog, power switching, or high-frequency RF device. In examples, herein high power is a power high enough that excess heat accumulated in the active channel that may affect the operation or reliability of the operation of the switch. For a more specific example, the structures and techniques herein may be applied to vertical diffused metal oxide semiconductor (VDMOS) FET type devices, lateral diffused metal oxide semiconductor (LDMOS) type devices, insulated-gate bipolar transistors (IGBT) as well as bipolar junction type devices. High power RF transistors have a maximum junction operating temperature for reliable operation. The junction temperature is determined by the power dissipation times the thermal impedance. The thermal impedance can be determined by the heat flow from the device junction or active region near the top surface of the die down through the die substrate material. The substrate material is usually a strong dielectric with poor thermal conductivity that degrades as the die temperature increases. The use of GaN on SiC to fabricate High Electron Mobility Transistors (HEMTs) enables much higher power densities than previous transistor technologies. Additionally, operation at increasing bias voltage also enables much higher power densities than operation at lower or reduced bias voltage. The higher power densities also generate more heat in a smaller area due to internal power dissipation. The smaller area of dissipation reduces the cross-sectional area of the heat dissipation path, which increases the junction temperatures. The auxiliary gate electrodes described herein reduce the junction temperature and allow the device to be operated within safe and reliable temperature margins. Alternatively, the various techniques increase the power conversion efficiency of the device which reduces the junction or channel temperature of the device by reducing the dissipated power without necessarily reducing the thermal impedance.

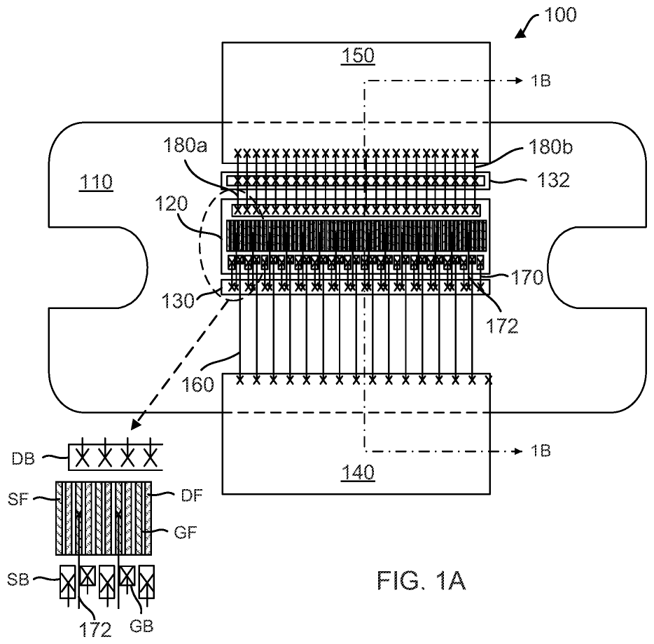

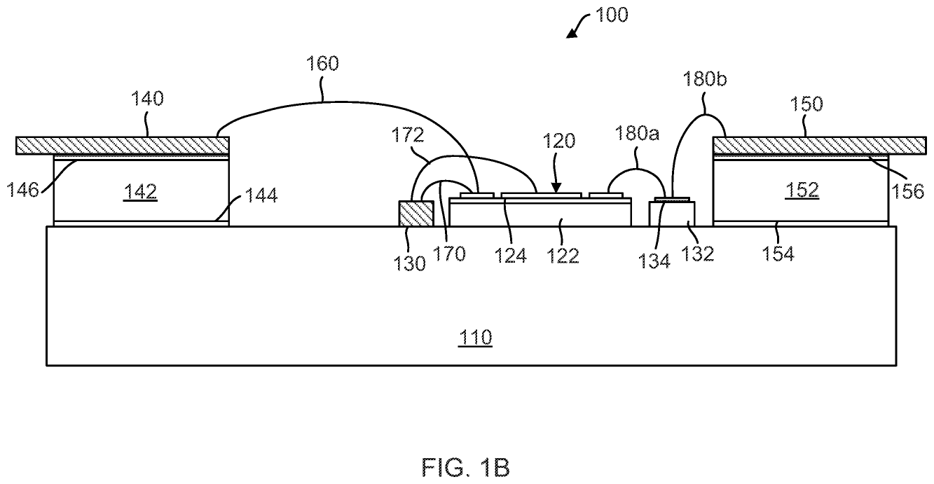

FIG. 1A is a top view diagram of an exemplary semiconductor power device 100 as a power device in accordance with an aspect of the disclosure. The semiconductor power device 100 includes a metallic (e.g., copper alloy) base plate 110 (e.g., a package flange, or printed circuit board (PCB)/RF laminate back-side integrated heat sink carrier in a “chip and wire” module technology), a semiconductor power die 120 disposed substantially on the base plate 110, a grounding metallic (e.g., copper alloy) bar 130 disposed substantially on the base plate 110, a bond support 132 disposed substantially on the base plate 110, an input lead 140 disposed substantially on the base plate 110 via an electrical insulator 142 (shown in FIG. 1B), and an output lead 150 disposed substantially on the base plate 110 via another electrical insulator 152 (shown in FIG. 1B). In this example, the semiconductor power die 120 is configured as a FET type device, such as a GaN on SiC HEMT, but other types of semiconductor power devices may be used. Although not shown, the semiconductor power device 100 may include a cover mounted substantially on the base plate 110 so as to enclose the semiconductor power die 120, metallic bar 130, bond support 132, and portions of the input and output leads 140 and 150. Further, the illustration shown in FIG. 1A (and FIG. 1B discussed below) may not be to scale. For example, the semiconductor power die 120 may be much smaller compared to the base plate 110, but is shown larger herein for description purposes. Additionally, depending on the output signal power requirement for the semiconductor power device 100, a plurality of semiconductor power dies 120 may be coupled in parallel between the input and output leads 140 and 150.

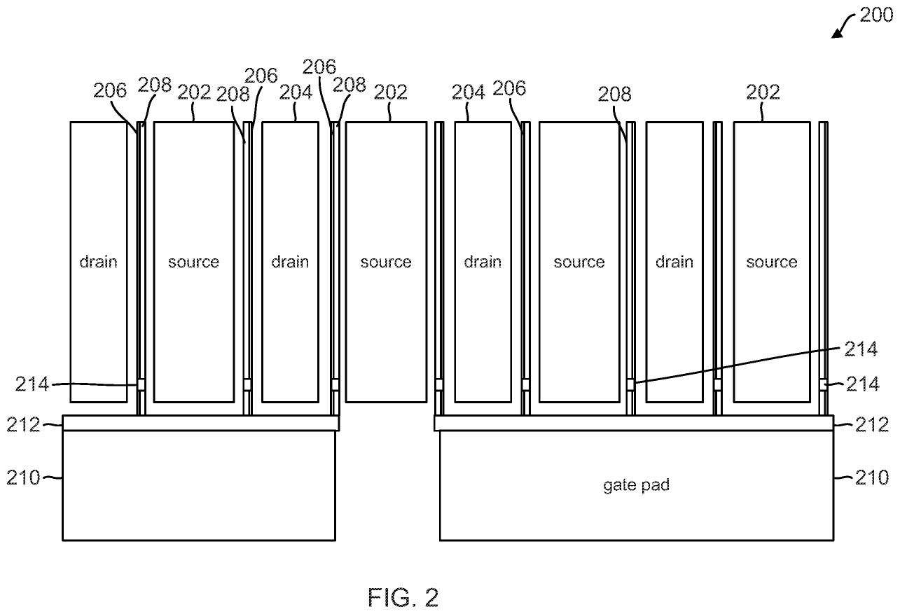

FIG. 1B is a cross-sectional side view diagram of the semiconductor power device 100 along line 1B-1B of FIG. 1A. The semiconductor power die 120 includes a SiC substrate 122 disposed substantially on the base plate 110, and a GaN layer 124 disposed on the SiC substrate 122. As viewed from the top (and better depicted in the enlarged portion shown in FIG. 1A), the top surface of the semiconductor power die 120 includes a set of gate bonding (metallization) pads (GB), a set of source bonding (metallization) pads (SB), a drain bonding (metallization) pad electrode (DB), a set of source (metallization) fingers (SF), a set of drain (metallization) fingers (DF), and a set of gate fingers (GF), all of which are disposed on the GaN layer 124. The structures are referred to as fingers in that they are elongated, along a common axis, as shown more clearly in FIG. 2. The source fingers are elongated parallel to the drain fingers and the gate fingers.

In this example, the region of the GaN layer 124 directly below the source, drain, and gate fingers (SF, DF, and GF) is the active region as that region constitutes the channel of the device 120. The region of the GaN layer 124 directly below the source, drain, and gate bonding pads (SB, DB, and GB) is not the active region as the channel of the device 120 is not situated directly below the bonding pads. As discussed in more detail herein, one or more auxiliary gate electrodes are disposed between one or more of the source fingers and/or the drain fingers to produce another thermal path between the active region of the device 120 and the top surface of the substrate. The auxiliary gate electrodes are also elongated as metallization layer fingers approximately parallel to and along the length of the main gate fingers. The top surface may be thermally coupled to the base plate in any of a variety of different ways. The top surface may be thermally coupled to a heat expander or package cover or container (not shown). The base plate or substrate substantially functions as a thermal ground. The single drain bonding pad (DB) could be designed as an array of smaller drain bond pads adjacent to each other. The semiconductor power device 100 further includes a set of wirebonds or conductive-ribbons (generally, electrical conductors) 160 electrically coupling the input lead 140 to the set of gate bonding pads (GB) of the semiconductor power die 120, respectively.

There may be other components (e.g., resistor, capacitor, and/or inductor, not shown) coupled between the input lead 140 and the set of gate bonding pads (GB) of the die 120, between the input lead 140 and the base plate 110, and/or the set of gate bonding pads (GB) and the base plate 110. Such components may be used to configure the semiconductor power device 100 with desirable characteristics, such as to improve the electrical or RF impedance match between the input of the semiconductor power device 100 and an input transmission line (not shown) coupled to the input lead 140. Alternatively, in a “chip and wire” implementation, the input lead 140 is the input transmission line itself.

Additionally, the semiconductor power device 100 includes another set of wirebonds or conductive-ribbons (generally, electrical conductors) 170 electrically coupling the set of source bonding pads (SB) of the semiconductor power die 120 to the base plate 110 via the metallic bar 130 for electrical grounding purposes. Also, the semiconductor power device 100 includes yet another set of wirebonds or conductive-ribbons (generally, electrical conductors) 180a electrically coupling the drain bonding pad (DB) of the semiconductor power die 120 to a top metallization layer 134 of the bond support 132, and another set of wirebonds or conductive ribbons (generally, electrical conductors) 180b electrically coupling the top metallization layer 134 of the bond support 132 to the output lead 150. The bond support 132 may be made of a relatively high thermal conductivity material, such as beryllium oxide (BeO), silicon carbide (SiC), diamond, graphite, or aluminum nitride (AlN), or a composite matrix of these with other materials or any other electrically insulating or semi-insulating thermal conductivity material for improving the heat removal from the semiconductor power die 120 via the one or more electrical conductors 180a. Similarly, there may be other components (e.g., resistor, capacitor, and/or inductor, not shown) coupled between the drain bonding pad (DB) of the semiconductor die 120 and the output lead 150, the drain bonding pad (DB) and the base plate 110, and/or the base plate 110 and the output lead 150. Such components may be used to configure the semiconductor power device 100 with desirable characteristics, such as to improve the electrical or RF impedance match between the output of the semiconductor power device 100 and an output transmission line (not shown) coupled to the output lead 150. Alternatively, in a “chip and wire” implementation, the output lead 150 is the input transmission line itself.

As better illustrated in FIG. 1B, the relative thickness (not shown to scale) between the GaN layer 124, the SiC substrate 122, and base plate 110 are shown. As an example, the GaN layer 124 may have a thickness of approximately 1 μm, the SiC substrate 122 may have a thickness of approximately 75-100 μm, and the base plate 110 may have a thickness of approximately 1000 μm. The base plate 110 may be made out of a high thermal and electrical conductivity material, such as a copper alloy. In “chip and wire” technology, the base plate 110 may be thicker up to centimeter scale and incorporate fins on the back or bottom side for air cooling or internal pipes for liquid cooling. During operation, the top surface or active region (e.g., FET channel) of the GaN layer 124 may be operating at temperatures around 200° C., while the base plate 110 may be operating at temperatures around 60° C. At 200° C., both the GaN layer 124 and the SiC substrate 122 have lower thermal conductivity (e.g., 140 and 180 W/m−K, respectively) compared to their thermal conductivity in operation at 60° C. An AlN or GaN nucleation layer used to grow GaN on SiC remains over the SiC and also has a low thermal conductivity that contributes to the overall poor thermal conduction out of the hot channel. Because the GaN layer 124 is very thin compared to the SiC substrate 122, the thermal impedance between the top surface or active region of the GaN layer 124 and the base plate 110 (which, because of its high thermal conductivity, substantially acts as thermal ground) is largely from the SiC substrate 122. Thus, as illustrated in FIG. 1B, the effective thermal impedance between the top surface of the GaN layer 124 and the base plate 110 is primary caused by the thermal impedance of the SiC substrate 122.

Optionally, the semiconductor power device 100 includes more electrical conductors 172 (e.g., wirebonds or ribbons) attached (e.g., bonded) at one end to one or more source fingers (SF) and attached (e.g., bonded) at the other end to the metallic bar 130 or to the base plate 110. The one or more electrical conductors 172 may also be used to provide electrical grounding for the source fingers in conjunction with the electrical conductors 170 from the set of source bonding pads (SB) to the base plate 110 via the metallic bar 130. Additional wirebonds may be applied to as thermal conductors or electrical grounds to other portions of the semiconductor power die.

To complete the description of the semiconductor power device 100, and with specific reference to FIG. 1B, the attachment of the semiconductor power die 120, metallic bar 130, and the bond support 132 to the base plate 110 may be performed in any reliable manner. As illustrated, the input lead 140 may be electrically attached to a top metallization layer 146 disposed on the electrical-insulator 142. The electrical-insulator 142, in turn, may be attached to the base plate 110 via a bottom metallization layer 144. Similarly, the output lead 150 may be electrically attached to a top metallization layer 156 disposed on the electrical-insulator 152. The electrical-insulator 152, in turn, may be attached to the base plate 110 via a bottom metallization layer 154. The semiconductor power die 120 receives an input signal from the input lead 140 via the set of electrical conductors 160. The semiconductor power die 120 performs some signal processing on (e.g., amplifying) the input signal to generate an output signal. The output signal is then routed to the output lead 150 via the sets of electrical conductors 180a and 180b).

FIG. 2 is a top view diagram of a portion of the semiconductor power die 120 of FIG. 1A showing main and auxiliary gate electrodes. The semiconductor power die 200, shown here as a FET has a series of main gate electrodes 206 formed as fingers of gate metallization layers over the substrate, also referred to as a base plate or flange between a series of source electrodes 202 shown as fingers of source metallization layers and a series of drain electrodes 204 formed as fingers of drain metallization layers. The source electrodes may be referred to as the common electrodes and the drain electrodes may be referred to as the output electrodes. A large electrical current flows through the active area from the source electrodes 202 to the corresponding drain electrode 204 whose magnitude is controlled or modulated by the much smaller main gate electrodes 206 which constitute the inputs. The source electrodes are coupled to source bonding pads (SB, not shown) and the drains are coupled to drain bonding pads (DB, not shown) as described above. The main gate electrodes 206 are coupled to gate pads 210 through a metallic gate bar 212. The configuration of pads and bars may be modified to suit different connection implementations.

The main gate electrode is small to reduce electrical charge transit time which is a requirement for high frequency operation. However, under high voltage and high current operation, a large amount of dissipated heat is generated at the drain-side edge of the gate electrode 206 and is diffused into the semiconductor crystal of the FET structure. Heat is generated in the active area adjacent to the main gate electrode. Due to the limited cross-sectional area of the main gate electrode, little heat can escape through the metal conductor of the main gate electrode, and a substantial amount of heat has to diffuse laterally to the source and drain metal electrode conductors. Nitride layers and BCB insulating layers are dielectrics that act like heat walls, so heat mainly flows downward through the 75-100 μm thick SiC substrate, and partially laterally through the source and drain metal conductors. The hottest spots tend to concentrate along the gate electrode and at the central or inner area of the die

The output power density of the die is improved by adding additional heat paths to the die layout in the form of auxiliary gate electrodes, inside the active area of the die. The auxiliary gate electrodes are formed inside the heat generating active area of the die and may be located extremely close or adjacent to the heat generating spots underneath the main gate electrode. The auxiliary gate electrodes may be formed of thick plated metal. In some examples the same thick plated metal may be used for making the thick auxiliary gate electrodes as are used for the source, and drain electrodes. The auxiliary gate electrodes may have a thickness of from 3μm to 5μm thick or even more and a width of 5 μm to 10 μm. These dimensions provide a cross-sectional area of 15 μm2 to 50 μm2, which is 30 to 100 times larger or greater than a typical main gate electrode. Accordingly, since the auxiliary gate electrodes are also thicker than the main gate electrodes, the auxiliary gate electrodes also have a larger or greater volume than the main gate electrodes.

In examples herein, a series of auxiliary gate electrodes 208 is introduced, as fingers formed of auxiliary metallization layers, and added to the FET beside the main gate electrodes 206. The auxiliary gate electrodes 208 are much larger than a nearby or adjacent main gate electrode 206 and it is electrically connected in parallel to the respective main gate electrode 206 at localized spots. The structures at these spots are referred to as gate extensions 214. The gate extensions 214 conduct heat into the connected auxiliary gate electrode 208 to diffuse quickly and efficiently from the semiconductor crystal to the main gate electrode 206 to the auxiliary gate electrode 208. The auxiliary gate electrode 208 extends laterally and vertically from the inner and hotter region of the active area to the outer and cooler region of the die. From the cooler regions, heat can outflow as a result of heat diffusion through a temperature gradient. The auxiliary gate electrodes, being thermally coupled to the respective main gate electrode are configured to draw heat from the main gate electrode away from the substrate. While only one gate extension 214 is shown for each main gate electrode, there may be many more. In some examples, each auxiliary gate electrode 208 has a plurality of gate extensions 214 spaced along the direction of elongation of the source electrodes 202

The gate extension 214 may be used for electrical and thermal connection. In this transistor die layout, the source and drain electrodes are arranged in an alternating pattern throughout the array. A parallel combination of a small (main) and large (auxiliary) gate electrodes lies between each source electrode and drain electrode. The main gate electrodes and auxiliary gate electrodes make an electrical and thermal, or heat joint, connection at several extension spots along the length of the gate electrode. There may be many pairs as shown in FIG. 2. The main gate electrodes 206 are elongated along the source electrodes 202 and the drain electrodes 204, in the same direction of elongation, or roughly parallel.

In between the source electrodes 202 and drain electrodes 204, a smaller main gate electrode 206 and a larger auxiliary gate electrode 208 are formed. The gate extensions make an electrical and heat joint connection at several locations along the gate electrodes. In this example, the connection is established every four extension spots along each main gate electrode 206. In another example, some or all of the main gate electrodes have more or less than four extension spots. In some examples the pattern of extension spots is different along different main gate electrodes.

GaN on SiC technology may be used to fabricate High Electron Mobility Transistors (HEMTs) with much higher power densities than previous transistor technologies. The higher power densities also generate more heat in a smaller area due to the internal power dissipation. The smaller area of dissipation reduces the cross-sectional area of the heat dissipation path, which increases the junction temperature.

While examples are described herein in the context of a high-power RF GaN on SiC die, the structures and techniques herein may be applied to any solid-state transistor technology being used at any frequency from DC to millimeter wave frequencies. High-power RF transistors have a maximum junction operating temperature that may be determined by the dissipated power (measured in watts) times the thermal impedance (measured in degrees, e.g., Celsius degrees, per watt). In typical applications, the thermal impedance is determined by the heat flow from the device junction at the top surface and inner region of the semiconductor die, down through the die substrate material.

Examples described herein provide an additional lateral path for heat flow that connects the topside, inner, and hotter regions of the semiconductor device to the topside, outer, and cooler regions and then down to the package flange through the outer and cooler regions of the semiconductor device. The modified heat flow results in a larger effective area for the generated heat to flow out of the semiconductor die, which translates into an equivalent reduced thermal resistance, and therefore into a lower peak junction temperature.

In the example GaN HEMT FET fabricated on a SiC substrate, the SiC has very high thermal conductivity at room temperature. The thermal conductivity decreases significantly as the temperature increases. In other words, heat flow is better through a cooler area of the SiC substrate than through a hotter area of the SiC substrate. In examples, the temperature at the bottom of the flange is limited but the top surface of the GaN die can be operated at much higher temperatures.

An inherent thermal path to flow excess heat from the channel is from the channel at the top of the semiconductor die 120, down through the GaN (1-2 μm thick) layer, next through the poor thermally conducting nucleation layer, and then through the SiC substrate layer (75-100 μm), and then through the flange 110 (˜1000 μm). The flange 110 is typically a copper alloy with good thermal conductivity. In some applications, this inherent thermal path limits the output power density (W/mm) which is limited by the corresponding power dissipation of the die 120.

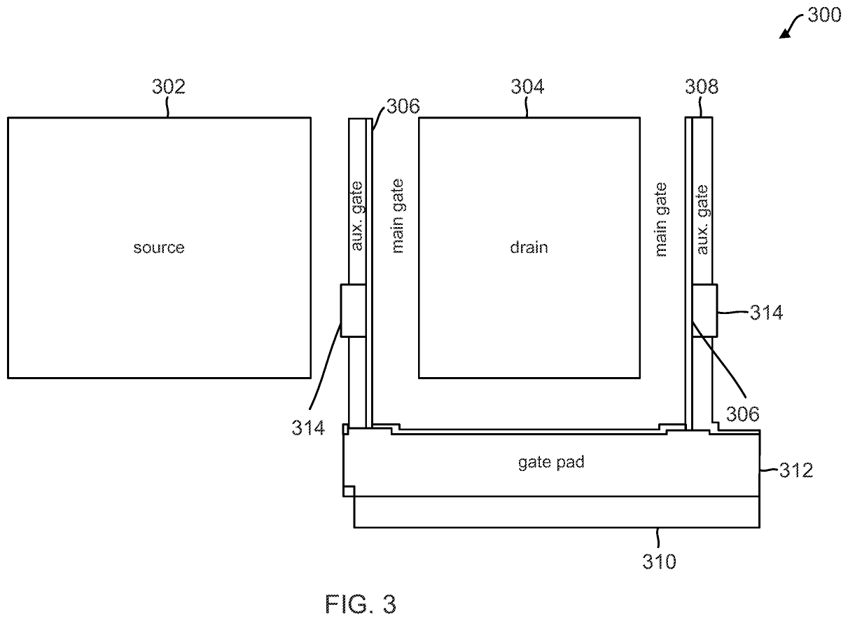

FIG. 3 is a top view diagram further enlarged of a portion 300 of the semiconductor power die of FIG. 2. A portion of a source electrode 302 and a portion of a drain electrode 304 are coupled outside the diagram to an input pad and an output pad, respectively. A gate pad 310 is coupled to each main gate electrode 306 through a metallic gate bar 312. The main gate electrodes 306 are shown as being thinner than any of the other structures. Auxiliary gate electrodes 308 are adjacent to and in this view appear to be in contact with the main gate electrodes 306. As described below, the auxiliary gate electrodes 308 are above and parallel to the respective main gate electrode 306 and extend in the same direction of elongation as all of the fingers of the source electrode and the drain electrode. The elongated auxiliary gate electrodes 308 are thermally and electrically coupled to the elongated main gate electrodes 306 by gate extensions 314.

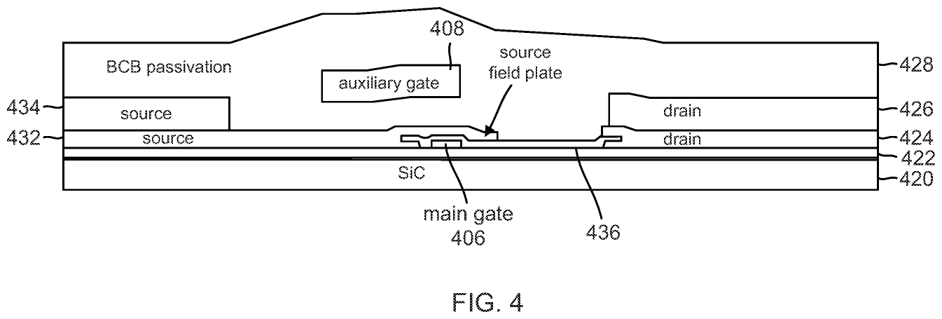

FIG. 4 is a two-dimensional side view cross-sectional diagram of a FET die structure through an area of the main gate electrode 406 in between two gate extension points. An auxiliary gate electrode 408 is visible as an additional but separated metal line above the main gate electrode 406. The auxiliary gate electrode 408 has a much larger cross-sectional area compared to the main gate electrode 406.

The FET die structure is formed on a substrate 420 of SiC or any other suitable dielectric material, e.g., glass, silicon, gallium nitride etc. The substrate 420 is covered with a GaN layer 422 and the other components are formed over the GaN layer 422. As shown, the alternating source electrodes 432, 434, drain electrodes 424, 426, and main gate electrodes 406 make up the fingers of a power FET. The small main gate electrode 406 is made with an evaporated metal, typically gold on top of a thin layer of nickel (not shown), which is 0.5 μm-1 μm thick and about 1 μm wide, which results in a cross-sectional area of at least 0.5-1 μm2, although the particular dimensions may be adapted to suit different applications. Source and drain metallization typically are made with a stack of evaporated 432, 422 and plated 424, 434 metal, typically more than 10 μm wide and about 5 μm thick, resulting in large metal conductors with a cross-sectional area of at least 50-100 μm2, although the particular dimensions may be adapted to suit different applications. A silicon nitride 436 layer is formed over the main gate electrode 406 and the surrounding passivation layer as a dielectric layer to better isolate the main gate electrode from the drain electrode and source electrode. A benzo-cyclobutene (BCB) passivation 428 layer is formed as another dielectric layer over the source electrode 434, main gate electrode 406, drain electrode 426, and the silicon nitride 436 layer. The silicon nitride 436 layer and the BCB passivation 428 thermally isolate the auxiliary gate electrode 408 from the main gate electrode 406. Silicon nitride 436 and benzo-cyclobutene (BCB) passivation 428 are insulating dielectric layers which are very poor heat conductors, but are used for electrical insulation, protection from moisture, and mechanical damage during assembly operations.

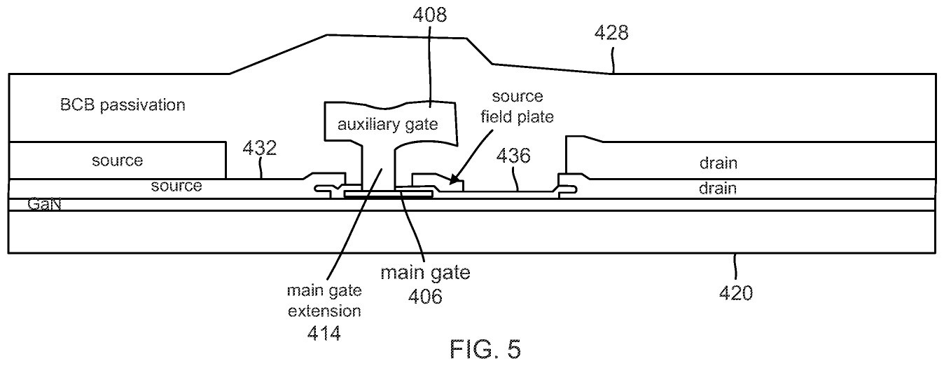

FIG. 5 is a two-dimensional side view cross-sectional diagram of the FET die structure of FIG. 4 through an area of the main gate electrode 406 at the gate extension zone 414. The auxiliary gate electrode 408 is visible with a gate extension 414 in the form of a direct metal VIA (Vertical Integrated Access) connection to the main gate electrode 406 that is below or underneath the respective auxiliary gate electrode 408. The VIA provides a direct electrical and thermal connection to the main gate electrode 406 as shown also in the horizontal views above. The VIA 414 extends from the auxiliary gate electrode 408 through the BCB passivation 428 layer and the silicon nitride 436 layer to the main gate electrode. Heat from the main gate electrode is conducted through the main gate extension 414 to the larger volume of the auxiliary gate electrode 408. In addition, heat in the surrounding areas including the BCB passivation 428 layer is conducted into the auxiliary gate electrode and distributed across the auxiliary gate electrode to dissipate through the BCB passivation layer an out to the substrate and flange (not shown) away from the active channel.

Thermal benefits may be significant at virtually no cost by forming the additional auxiliary gate electrodes and gate extensions with the source and drain electrodes. The added gate extension may result in a 10° C. lower peak channel temperature for an RF switching power FET. The heat sources underneath the auxiliary gate electrodes, may have a still greater peak temperature reduction of 20° C. to 30° C.

Electrical benefits may include a lower input (gate) resistance and an increased input capacitance which translate into a reduced complex input impedance (from gate to source) Zgs. The reduced input impedance improves signal propagation through the fingers of the main gate electrode of the transistor. The reduced input impedance also affects the negative feedback from the drain to the main gate electrode which causes a reduced deviation in the total input signal.

The increased input capacitance increases the filtering of the harmonics of the fundamental frequency. This improvement, especially of the second and higher harmonics at the input, enables further high efficiency circuit optimization techniques which also contribute to less heat dissipation. In tests on kilowatt rated transistors, there may be a 10% efficiency points improvement at L-band, and more than 5% points at S-band.

The configuration of the auxiliary gate electrode may be modified to suit different thermal demands and fabrication processes. The auxiliary gate electrodes may be made larger or smaller. There may be more or fewer auxiliary gate electrodes. The extensions that connect the auxiliary gate electrode to the main gate electrodes may be made larger or smaller or more or less numerous.

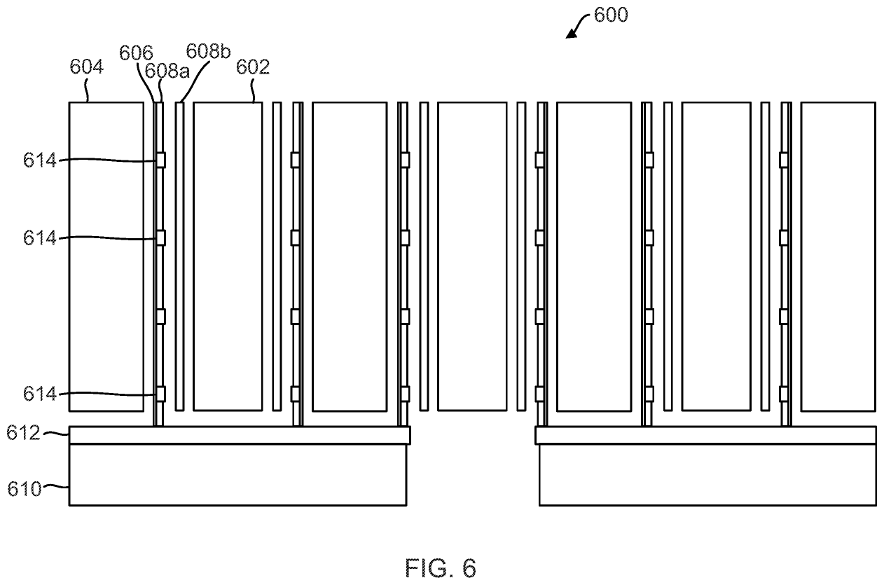

FIG. 6 is a top view enlarged diagram of alternating source, drain, and gate regions as fingers of a portion 600 of an alternative power FET. The semiconductor power die 600, shown here as a FET has a series of main gate electrodes 606 formed as fingers of gate metallization layers over the substrate, also referred to as a base plate or flange between a series of source electrodes 602 shown as fingers of source metallization layers and a series of drain electrodes 604 formed as fingers of drain metallization layers. A series of auxiliary gate electrodes 608a is disposed over and beside each respective main gate electrode 606. The auxiliary gate electrodes 608 have a configuration similar to that described above, being formed as fingers of auxiliary gate metallization layers, and are electrically and thermally connected in parallel to the respective main gate electrode 606 through gate extensions 614 in the form of VIAs, vertical electrodes, wires, or another suitable structure.

In this alternative example, the connections 614 between the main gate electrodes 606 and the auxiliary gate electrodes 608a are made at every gate extension zone along the electrode. The main gate electrodes 606 are elongated along the source electrodes 602 and the drain electrodes 604, in the same direction, or roughly parallel. Each auxiliary gate electrode 608, as shown, has a plurality of gate extensions 614 spaced along the direction of elongation of the source electrodes 202. The multiple gate extensions 614 may also be added to the example of FIG. 2. Another auxiliary gate electrode 608b is also coupled in parallel to each main gate electrode 606, to the first auxiliary gate electrode 608a, or both to further enhance the heat extraction and the input impedance reduction of the FET. The second auxiliary gate electrodes 608b are alongside at least a portion of the plurality of auxiliary gate electrodes 608a. In some examples, some of the auxiliary gate electrodes are thermally coupled only to other auxiliary gate electrodes or to an auxiliary gate electrode and to a main gate electrode. Such a connection may be made using additional VIAs to the main gate electrode. If the second auxiliary gate electrodes 608b are above the main gate electrodes 606 at or near the level of the first auxiliary gate electrodes 608a, then the second auxiliary gate electrodes 608b may be thermally coupled to a respective first auxiliary gate electrode 608a or main gate electrode 606 through a lateral bridge (not shown). The larger number of extension points extract heat more effectively. The equivalent input gate capacitance and resistance are also positively affected by the improved heat extraction. Other configurations of gate extension zones and auxiliary gate electrodes may made, e.g., to suit different operating frequencies, signal pulse width., duty cycle, power output, packaging constraints and other design goals.

The number of connections made by the extension zones may be characterized as a periodicity. In this example, the periodicity of the connections from the auxiliary gate to the main gate is substantially every 50 micrometers (μm). The value of the periodicity as a distance may vary with different size features and transistors. By contrast in the example of FIG. 2, the periodicity of the connections from the auxiliary gate to the main gate is substantially every 200 μm. The periodicity affects thermal impedance between the gate region and the package flange, and the electrical performance (e.g., input impedance) for the FET. The transistor may be fabricated with a periodicity that is selected to meet the desired thermal and electrical impedance.

As a further alternative, the connections from the auxiliary gate to the main gate may be configured as not periodic or regular within the main gate fingers. In some examples, the connections may be spaced apart at irregular intervals in order to obtain desired thermal and electrical characteristics.

As a further alternative, the configuration and physical characteristics of the connections may be varied. Although in the examples of FIGS. 2 and 6, the connections of the auxiliary gate to the main gate for all gate fingers are configured substantially the same, the connections may be configured differently from finger-to-finger. For example, the connections from the auxiliary gate to the main gate for fingers centrally located within the FET may be more numerous or have a higher density than for fingers located towards the lateral ends of the FET. As another example, some gate fingers may include auxiliary gates and other gate fingers may not include auxiliary gates.

Further, as suggested by the depiction of FIG. 6, each gate finger may include more than one auxiliary gate connected to the corresponding main gate. Some gate fingers may have more auxiliary gate electrodes and some gate fingers may have fewer auxiliary gate electrodes.

The thermal performance of the transistors as described herein may be enhanced in other ways using additional thermal configurations and structures. As an example, the gate pad as shown in FIGS. 2 and 3 may be used to great effect as a heat sink. The source and drain pads may also be used in this way. The gate pad is electrically connected to both the auxiliary gate electrodes and the main gate electrodes. There is a thermal path to the package flange through the FET substrate as mentioned above. However, for still lower thermal impedance to the package flange, additional wire bonds or ribbons may be provided to thermally, but not electrically, couple the gate pad to the package flange

The present disclosure is provided to enable any person skilled in the art to make or use the structures and techniques herein. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A semiconductor power die comprising:
a substrate;
a plurality of source electrodes formed as fingers of source metallization layers over the substrate;
a plurality of drain electrodes formed as fingers of drain metallization layers over the substrate;
a plurality of main gate electrodes, each being between a source electrode and a drain electrode;
a dielectric layer over the plurality of source electrodes, the plurality of drain electrodes, and the plurality of main gate electrodes; and
a plurality of auxiliary gate electrodes, each being between a source electrode and a drain electrode, and above a respective main gate electrode with a dielectric layer between the main gate electrode and the respective auxiliary gate electrode, the auxiliary gate electrodes being thermally coupled to the respective main gate electrode and configured to draw heat from the main gate electrode away from the substrate.

2. The semiconductor power die of claim 1, further comprising a top surface opposite the substrate and wherein the auxiliary gate electrodes are configured to draw heat in a direction from an active area of the semiconductor power die.

3. The semiconductor power die of claim 1, wherein the auxiliary gate electrodes are formed of auxiliary metallization layers over the substrate, the auxiliary metallization layers being formed of the same material as the source metallization layers.

4. The semiconductor power die of claim 1, wherein the auxiliary gate electrodes have a greater cross-sectional area than the main gate electrodes.

5. The semiconductor power die of claim 1, wherein the auxiliary gate electrodes have a greater volume than the main gate electrodes.

6. The semiconductor power die of claim 1, wherein a main gate electrode has a cross-sectional area no greater than 1 square micrometer and the auxiliary gate electrode has a cross-sectional area of at least 15 square micrometers.

7. The semiconductor power die of claim 1, wherein the auxiliary gate electrodes are over a respective main gate electrode and over a respective source gate electrode.

8. The semiconductor power die of claim 1, further comprising a plurality of gate extensions each connected to an auxiliary gate electrode and to a respective main gate electrode, wherein the auxiliary gate electrodes are thermally coupled to the respective main gate electrodes through the respective gate extensions.

9. The semiconductor power die of claim 8, wherein the gate extensions are formed as VIAs (Vertical Integrated Accesses).

10. The semiconductor power die of claim 8, wherein the main gate electrodes are elongated along the source electrodes and the drain electrodes and wherein each auxiliary gate electrode has a plurality of gate extensions spaced along the direction of elongation of the source electrodes.

11. The semiconductor power die of claim 1, wherein the auxiliary gate electrodes are elongated along respective fingers of the source electrodes, the semiconductor power die further comprising a second auxiliary gate electrode elongated in the direction of the fingers of the source electrode, alongside at least a portion of the plurality of auxiliary gate electrodes.

12. The semiconductor power die of claim 11, wherein the second auxiliary gate electrodes are thermally coupled to a respective main gate electrode.

13. The semiconductor power die of claim 12, wherein the second auxiliary gate electrodes are thermally coupled to a respective main gate electrode through a respective first auxiliary gate electrode.

14. The semiconductor power die of claim 12, wherein the second auxiliary gate electrodes are thermally coupled to a respective main gate electrode through a plurality of VIAs.

15. The semiconductor power die of claim 12, wherein the second auxiliary gate electrodes are thermally coupled to a respective main gate electrode through a lateral bridge.

16. The semiconductor power die of claim 1, wherein the substrate is attached to a package flange, the semiconductor power die further comprising a gate pad electrically coupled to the plurality of main and auxiliary gate electrodes and thermal conductors coupled to the gate pad to the package flange.

17. A semiconductor power device, comprising:
a base plate;
an input lead;
an output lead;
a field effect transistor (FET) power die disposed over the base plate, wherein the FET power die includes a set of source electrodes, a set of drain electrodes, and a set of gate electrodes disposed directly over an active region, wherein the set of gate fingers is configured to receive an input signal from the input lead, and wherein the FET power die is configured to process the input signal to generate an output signal at the set of drain fingers for routing to the output lead, the FET power die comprising:
a substrate attached to the base plate;
a dielectric layer over the plurality of source electrodes, the plurality of drain electrodes, and the plurality of main gate electrodes; and
a plurality of auxiliary gate electrodes, each being between a source electrode and a drain electrode, and above a respective main gate electrode with a dielectric layer between the main gate electrode and the respective auxiliary gate electrode, the auxiliary gate electrodes being thermally coupled to the respective main gate electrode and configured to draw heat from the main gate electrode away from the substrate.

18. The semiconductor power device of claim 17, wherein the auxiliary gate electrodes are over a respective main gate electrode and over a respective source gate electrode.

19. The semiconductor power device of claim 17, further comprising a plurality of gate extensions each connected to an auxiliary gate electrode and to a respective main gate electrode, wherein the auxiliary gate electrodes are thermally coupled to the respective main gate electrodes through the respective gate extensions.

20. The semiconductor power device of claim 19, wherein the main gate electrodes are elongated along the source electrodes and the drain electrodes and wherein each auxiliary gate electrode has a plurality of gate extensions spaced along the direction of elongation of the source electrodes.
